(19) United States
(12) Patent Application Publication
(10) Pub. No.: US 2025/0079789 A1
(43) Pub. Date: Mar. 6, 2025

(54) LIGHT-EMITTING DEVICE

(71) Applicant: NICHIA CORPORATION, Tokushima (JP)

(72) Inventor: Tetsuya TOMINAGA, Anan-shi (JP)

(73) Assignee: NICHIA CORPORATION, Tokushima (JP)

(21) Appl. No.: 18/815,794

(22) Filed: Aug. 26, 2024

(30) Foreign Application Priority Data
Aug. 31, 2023 (JP) 2023-141392

(51) Int. Cl. H01S 5/02253; H01S 5/06; H01S 5/068

(52) U.S. Cl. CPC H01S 5/02253; H01S 5/0611; H01S 5/06804

(57) ABSTRACT

A light-emitting device includes a light source, a lens disposed above the light source, and a light-receiving element disposed at a position not intersecting with an optical axis of the lens and receiving external light via the lens. The lens includes a light adjustment part in a region overlapping the light-receiving element in a top view, and the light adjustment part for adjusting an amount of external light received by the light-receiving element.

### CROSS REFERENCE TO RELATED APPLICATION

This application claims priority benefit of Japanese Patent Applications No. 2023-141392, filed on Aug. 31, 2023, and the entire contents of which are hereby incorporated by reference and made a part of this specification.

### BACKGROUND

### Technical Field

The present disclosure relates to a light-emitting device.

### Background Art

There has been a known light-emitting device that can adjust the amount of light emitted by a light source in accordance with the amount of external light received by a light-receiving element. For example, Japanese Patent Publication No. 2016-72574 discloses a light-emitting device including a light source, a light-receiving element, and a lens disposed on the light source and the light-receiving element and having a surface subjected to emboss processing.

### SUMMARY

The present disclosure provides a light-emitting device having high accuracy in adjustment of a light emission amount of the light-emitting device.

A light-emitting device according to an embodiment of the present disclosure includes a light source, a lens disposed above the light source, and a light-receiving element disposed at a position not intersecting with an optical axis of the lens and receiving external light via the lens. The lens includes a light adjustment part in a region overlapping the light-receiving element in a top view. The light adjustment part is configured to adjust an amount of external light received by the light-receiving element.

According to one embodiment of the present disclosure, the accuracy in adjustment of a light emission amount of a light-emitting device can be improved.

### BRIEF DESCRIPTION OF DRAWINGS

FIG. 1 is a schematic top view illustrating an example of a smartphone including a light-emitting device according to a first embodiment.

FIG. 2 is a schematic cross-sectional view of the light-emitting device taken along line II-II in FIG. 1.

FIG. 3 is a diagram illustrating an example of the transition in the amount of received light depending on an incident angle of external light.

FIG. 4 is a schematic view explaining an action of a light adjustment part provided in a lens of the light-emitting device according to the first embodiment.

FIG. 5 is a schematic view explaining an action of the light adjustment part provided in the lens of the light-emitting device according to the first embodiment.

FIG. 6A is a diagram explaining an example of the effect of reducing variation in the amount of light received by the light-emitting device according to the first embodiment.

FIG. 6B is a diagram explaining an example of the effect of reducing variation in the amount of light received by the light-emitting device according to the first embodiment.

FIG. 7A is a diagram explaining another example of the effect of reducing variation in the amount of light received by the light-emitting device according to the first embodiment.

FIG. 7B is a diagram explaining another example of the effect of reducing variation in the amount of light received by the light-emitting device according to the first embodiment.

FIG. 8 is a schematic cross-sectional view of a light-emitting device according to a second embodiment taken along an XZ plane.

FIG. 9A is a diagram explaining an example of the effect of reducing variation in the amount of light received by the light-emitting device according to a second embodiment.

FIG. 9B is a diagram explaining an example of the effect of reducing variation in the amount of light received by the light-emitting device according to the second embodiment.

### DETAILED DESCRIPTION

Light-emitting devices according to embodiments of the present disclosure are described in detail below with reference to the drawings. The embodiments described below are intended as examples of light-emitting devices for giving a concrete form to the technical idea of the present invention, and are not intended to limit the present invention thereto. Further, dimensions, materials, shapes, relative arrangements, or the like of constituent members described in the embodiments are not intended to limit the scope of the present disclosure thereto, unless otherwise specified, and are merely exemplary. Note that the size, positional relationship, or the like of members illustrated in each of the drawings may be exaggerated for clarity of description. In the following description, members having the same terms and reference signs represent the same members or members of the same material, and a detailed description of these members is omitted as appropriate. As a cross-sectional view, an end view illustrating only a cut surface may be used.

In the following drawings, directions may be indicated by an X axis, a Y axis, and a Z axis. The X axis, the Y axis, and the Z axis are orthogonal to one another. A direction along the X-axis in which an arrow points is referred to as a +X direction and a direction opposite to the +X direction is referred to as a −X direction. A direction along the Y-axis in which an arrow points is referred to as a +Y direction, and a direction opposite to the +Y direction is referred to as a −Y direction. A direction along the Z-axis in which an arrow points is referred to as a +Z direction and a direction opposite to the +Z direction is referred to as a −Z direction. Also, the term “in a top view” used in the embodiments refers to viewing an object from a position located further in the +Z direction. However, this does not limit the orientation of the light-emitting device during use, and the orientation of the light-emitting device may be any chosen orientation. In the embodiments, a surface of a target object when viewed from a position located further in the +Z direction is referred to as an “upper surface,” and a surface of the target object when viewed from a position located further in the −Z direction is referred to as a “lower surface”. In the following embodiments, the phrase “being aligned with the X axis, the Y axis, and the Z axis” encompasses being at an inclination within a range of ±10° relative to these axes. In the following embodiments, the term “orthogonal” may include a deviation within ±10° with respect to 90°.

In the present disclosure, polygonal shapes such as triangles and quadrangles encompass modified shapes, such as polygonal shapes in which the corners of the polygon are rounded, chamfered, beveled, coved, and the like. Not only shapes with modified corners (ends of a side) but also shapes in which intermediate portions of sides are modified are also referred to as a polygon. That is, a polygon-based shape with modified portion is included in the interpretation of the “polygonal shape” described in the present disclosure.

This applies not only to polygonal shapes but also to other terms representing specific shapes such as trapezoids, circles, protrusions, and recesses. The same also applies the terms related to each side forming the shape. That is, even when a corner or an intermediate portion of a side is modified, the interpretation of “side” includes the modified portion.

### First Embodiment

### Example of Overall Configuration of Light-Emitting Device

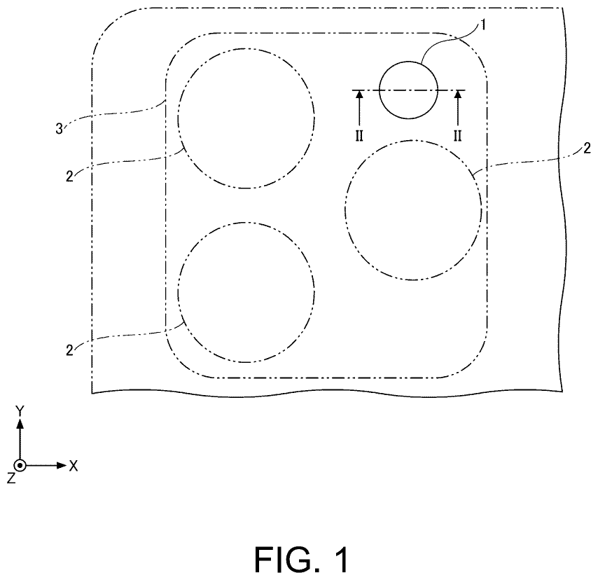

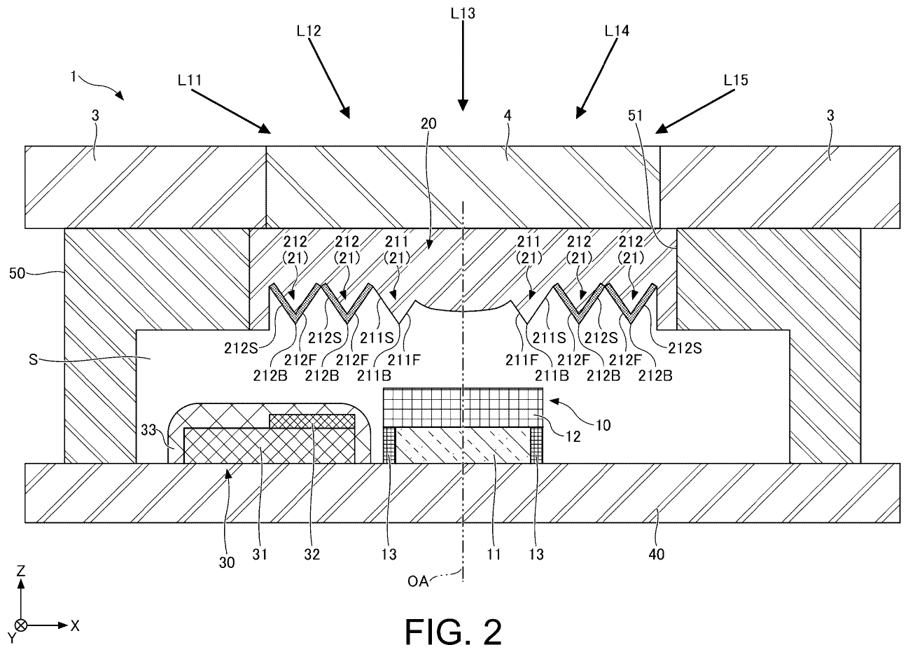

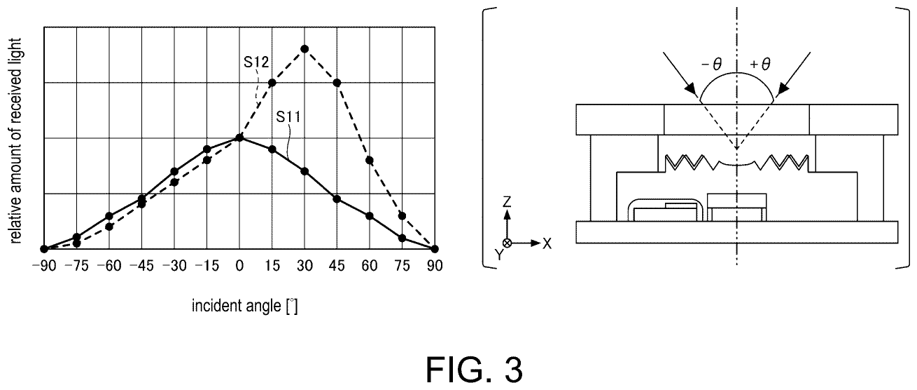

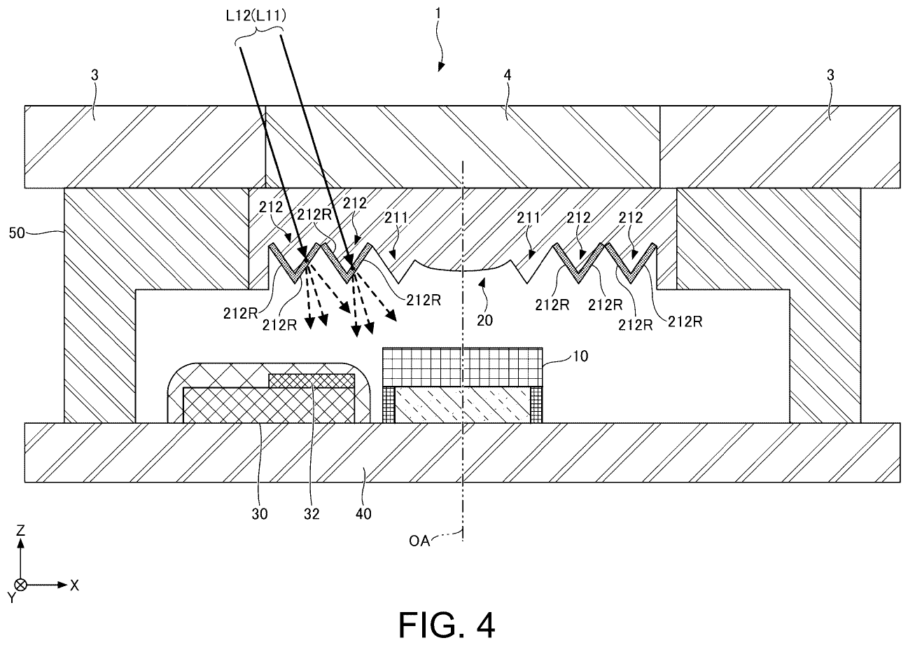

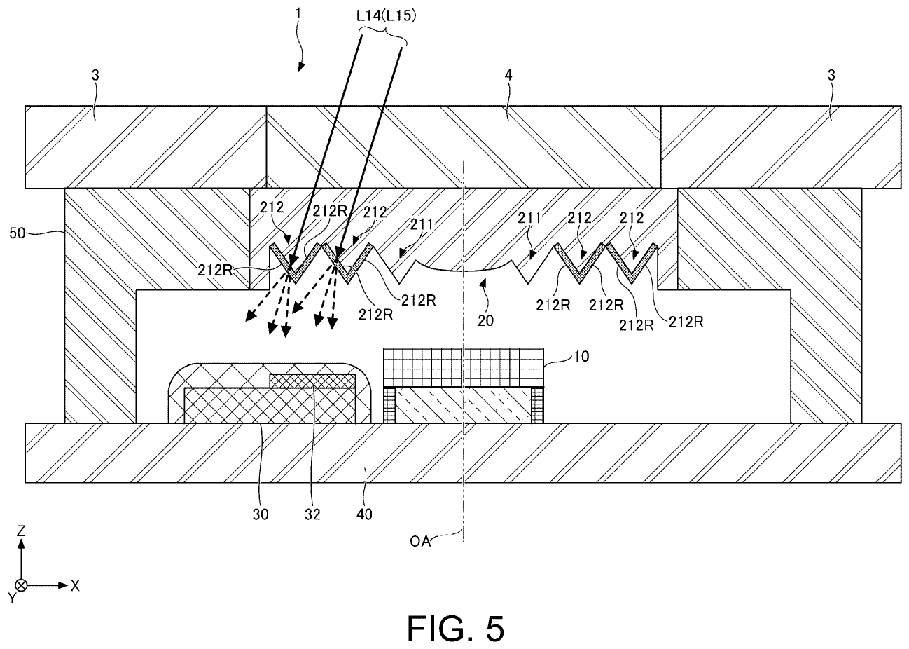

The overall configuration of a light-emitting device according to a first embodiment is described with reference to FIG. 1 to FIG. 5. FIG. 1 is a schematic top view illustrating an example of a smartphone including a light-emitting device 1 according to the first embodiment. FIG. 2 is a schematic cross-sectional view of the light-emitting device 1 taken along line II-II in FIG. 1. FIG. 3 is a diagram illustrating an example of the transition in the relative amount of received light depending on an incident angle of external light. FIG. 4 and FIG. 5 are schematic views illustrating an action of a light adjustment part provided in a lens 20 of the light-emitting device 1 according to the first embodiment.

The light-emitting device 1 is, for example, a light-emitting device for a flash for an imaging device 2 provided in a smartphone. Examples of the imaging device 2 include a camera for capturing a still image and a camera for capturing a moving image. The light-emitting device 1 is accommodated in a housing 3 of the smartphone together with the imaging device 2. As illustrated in FIG. 1, the light-emitting device 1 is disposed in the vicinity of the imaging device 2.

As illustrated in FIG. 2, the light-emitting device 1 includes a light source 10, a lens 20, and a light-receiving element 30. The light-emitting device 1 may further include a substrate 40 on which each of the light source 10 and the light-receiving element 30 is mounted, and a support portion 50 supporting the lens 20. The light-emitting device 1 may include electronic components such as a Zener diode, a thermistor, and a capacitor. These electronic components can be mounted on the substrate 40 as constituent members of the light-emitting device 1 together with the light source 10 and the light-receiving element 30.

For example, the light source 10 emits light in accordance with a timing at which the imaging device 2 captures an image of a subject. The lens 20 transmits the light emitted by the light source 10 and allows the transmitted light to exit it to the outside of the light-emitting device 1. The light-receiving element 30 receives external light from the sun, various lighting fixtures, or the like via the lens 20. In the light-emitting device 1, the amount of light emitted by the light source 10 is adjusted in accordance with the amount of external light received by the light-receiving element 30.

The light-emitting device 1 has an upper surface, a lower surface, and one or more lateral surfaces connecting the upper surface and the lower surface. As illustrated in FIG. 2, the upper surface of the light-emitting device 1 corresponds to an upper surface of the lens 20 and an upper surface of the support portion 50. The lower surface of the light-emitting device 1 corresponds to a lower surface of the substrate 40. The lateral surface of the light-emitting device 1 corresponds to an outer lateral surface of the support portion 50.

The lens 20 is fixed above the light source 10 by being supported by the support portion 50. Thus, as illustrated in FIG. 2, a hollow space S surrounded by the support portion 50 is formed inside the light-emitting device 1. The light source 10 and the light-receiving element 30 are accommodated in the space S in a state of being disposed at different positions on an upper surface of the substrate 40. The light source 10 and the light-receiving element 30 are accommodated in the same space S, and thus the light-emitting device 1 can be reduced in size. Each of the light source 10 and the light-receiving element 30 is not exposed to the outside of the light-emitting device 1, which can increase the degree of freedom in design of a smartphone or the like incorporating the light-emitting device 1.

The lens 20 is disposed above the light source 10 and the light-receiving element 30. A light extraction surface corresponding to an upper surface of the light source 10 faces a lower surface of the lens 20. Light emitted by the light source 10 enters the lens 20 through the lower surface of the lens 20 and exits the lens 20 through the upper surface of the lens 20. On the other hand, external light enters the lens 20 through the upper surface of the lens 20 and exits the lens 20 through the lower surface of the lens 20. When the external light exiting from the lower surface of the lens 20 reaches the light-receiving element 30, the light-receiving element 30 detects the external light.

The substrate 40 is a member on which the light source 10 and the light-receiving element 30 are disposed. The substrate 40 includes a wiring and a base supporting the wiring. The substrate 40 is a plate-shaped member having a substantially rectangular outer shape in a top view. However, the substrate 40 may have another outer shape such as a substantially circular shape, a substantially elliptical shape, or a substantially polygonal shape in a top view.

The wiring is connected to an external power source and supplies power to the light source 10. The wiring includes, for example, an upper surface wiring disposed on the upper surface of the substrate 40, an intermediate wiring such as a via wiring penetrating the substrate 40, a lower surface wiring disposed on the lower surface of the substrate 40, and the like. Each of the light source 10 and the light-receiving element 30 is connected to the upper surface wiring. For the wiring, a metal material can be used, and for example, an elemental metal such as gold (Au), silver (Ag), aluminum (Al), nickel (Ni), rhodium (Rh), copper (Cu), titanium (Ti), platinum (Pt), palladium (Pd), molybdenum (Mo), Chromium (Cr), and tungsten (W), or alloys containing these metals can be suitably used. Examples of the base for supporting the wiring include ceramic substrates made of aluminum nitride, aluminum oxide, silicon nitride, and the like, and resin substrates made of glass epoxy and the like. However, the substrate 40 is not limited thereto.

The support portion 50 supports the lens 20. In the light-emitting device 1, the lens 20 can be disposed above the light source 10 to be separated from the light source 10 by the support portion 50. The support portion 50 has a substantially rectangular outer shape in a top view. However, in a top view, the support portion 50 may have another outer shape such as a substantially circular shape, a substantially elliptical shape, or a substantially polygonal shape.

The support portion 50 is attached to the upper surface of the substrate 40. The support portion 50 surrounds the light source 10 and the light-receiving element 30 in a top view. The support portion 50 includes a through hole 51, and the lens 20 is supported by the support portion 50 in a state of being fitted into the through hole 51. The support portion 50 is preferably a light-shielding member. When the support portion 50 is a light-shielding member, light emitted from the light source 10 can be inhibited from being transmitted through the support portion 50 and from being emitted to the outside of the light-emitting device 1.

When the light-emitting device 1 is used as a flash light source of a smartphone, the light-emitting device 1 is disposed such that the support portion 50 overlaps the housing 3 of the smartphone in a top view. In a top view, the lens 20 is disposed to overlap a cover glass 4 disposed in an opening of the housing 3. However, when the cover glass 4 is not provided in the housing 3, the upper surface of the lens 20 may be exposed to the outside from the opening. In a top view, it is preferable that the through hole 51 of the support portion 50 overlaps the opening of the housing 3 or encloses the opening of the housing 3. Thus, the support portion 50 is less likely to be visually recognized from the outside of the smartphone.

### [Light Source 10]

The configuration of the light source 10 will be described below. As illustrated in FIG. 2, the light source 10 is disposed on the upper surface of the substrate 40 to intersect an optical axis OA of the lens 20. In the light-emitting device 1, the light source 10 and the lens 20 are preferably disposed such that the center of the light source 10 intersects the optical axis OA of the lens 20.

The light source 10 has the upper surface, a lower surface, and one or more lateral surfaces connecting outer edges of the upper surface and the lower surface. The light source 10 has a substantially rectangular outer shape in a top view. However, the light source 10 may have another outer shape such as a substantially circular shape, a substantially elliptical shape, or a substantially polygonal shape in a top view.

As illustrated in FIG. 2, the light source 10 includes a light-emitting element 11, a wavelength conversion member 12, and a light-shielding member 13. The light source 10 emits white light. However, light emitted by the light source 10 is not limited to white light, and may be light having a specific wavelength such as blue light. The wavelength and chromaticity of the light emitted by the light source 10 may be selected as appropriate in accordance with the intended use of the light-emitting device 1.

The light-emitting element 11 is disposed on the upper surface of the substrate 40. The light-emitting element 11 includes positive and negative electrodes connected to the wiring of the substrate 40. Thus, power from the external power source is supplied to the light-emitting element 11. The light-emitting element 11 has a rectangular outer shape in a top view. However, the light-emitting element 11 may have another outer shape such as a substantially circular shape, a substantially elliptical shape, or a substantially polygonal shape in a top view.

The light-emitting element 11 is a semiconductor light-emitting element such as a light emitting diode (LED) or a laser diode (LD). The light-emitting element 11 is preferably made of a semiconductor such as a III-V compound semiconductor or a II-VI compound semiconductor. An example of the semiconductor constituting the light-emitting element 11 includes a nitride semiconductor such as In_{X}Al_{Y}Ga_{1-X-Y}N (0≤X, 0≤Y, X+Y≤1).

A light emission peak wavelength of the light-emitting element 11 is preferably in a range from 400 nm to 530 nm, more preferably in a range from 420 nm to 490 nm, even more preferably in a range from 450 nm to 475 nm from the viewpoint of light emission efficiency, excitation of a wavelength conversion material, and the like. The light-emitting element 11 emits blue light belonging to these wavelength regions.

The wavelength conversion member 12 is disposed on the light-emitting element 11. The wavelength conversion member 12 is a plate-shaped member having a rectangular outer shape in a top view. However, the wavelength conversion member 12 may have another outer shape such as a substantially circular shape, a substantially elliptical shape, or a substantially polygonal shape.

The wavelength conversion member 12 includes a wavelength conversion layer configured to convert the wavelength of light emitted by the light-emitting element 11, and a light diffusion layer disposed on the wavelength conversion layer. An upper surface of the light diffusion layer corresponds to the upper surface of the light source 10. That is, the upper surface of the light diffusion layer corresponds to the light extraction surface of the light source 10.

The wavelength conversion layer of the wavelength conversion member 12 includes a base material containing a light-transmissive material and a wavelength conversion material contained in the base material. The “light-transmissive” refers to being configured to transmit 60% or more of the light emitted by the light-emitting element 11. Examples of the light-transmissive material include resin materials, ceramics, and glass. In the present embodiment, the light-transmissive material constituting the base material of the wavelength conversion layer includes a resin material. Examples of the resin material include a silicone resin, a silicone-modified resin, an epoxy resin, an epoxy-modified resin, and a phenol resin. In particular, a silicone resin or a modified resin thereof with good light resistance and heat resistance is preferable. However, the light-transmissive material is not limited thereto.

Examples of the wavelength conversion material included in the wavelength conversion layer include an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), oxynitride-based phosphors such as a β-SiAlON-based phosphor (for example, (Si,Al)₃(O,N)₄:Eu) and an α-SiAlON-based phosphor (for example, Ca(Si,Al)₁₂(O,N)₁₆:Eu), nitride-based phosphors such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr,Ca)AlSiN₃:Eu), fluoride-based phosphors such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI group quantum dot (for example, CdSe), a III-V group quantum dot (for example, InP), and a quantum dot having a chalcopyrite structure (for example, (Ag,Cu)(In,Ga)(S,Se)₂). The wavelength conversion material of the present embodiment contains an yttrium aluminum garnet (YAG)-based phosphor having good heat resistance. A part of the blue light emitted from the light-emitting element 11 is converted into yellow light by the YAG-based phosphor. Thus, white light is emitted from the light extraction surface of the light source 10.

The light diffusion layer of the wavelength conversion member 12 is disposed on the wavelength conversion layer. The light diffusion layer includes a base material containing a light-transmissive material and a light diffusion material dispersed in the base material. The light-transmissive material constituting the base material of the light diffusion layer may be the same material as the light-transmissive material constituting the base material of the wavelength conversion layer or may be a material different from that. In the present embodiment, the light-transmissive material constituting the base material of the light diffusion layer includes a silicone resin. However, the light-transmissive material is not limited thereto.

The light diffusion material of the light diffusion layer diffuses light emitted from the wavelength conversion layer. Examples of the light diffusion material include titanium oxide, barium titanate, aluminum oxide, and silicon oxide. However, the light diffusion material is not limited thereto.

The light-shielding member 13 covers lateral surfaces of the light-emitting element 11. The light-shielding member 13 may also cover lateral surfaces of the wavelength conversion member 12. Outer edges of the light-shielding member 13 form a substantially rectangular outer shape in a top view. However, the outer edges of the light-shielding member 13 may form another outer shape such as a substantially circular shape, a substantially elliptical shape, or a substantially polygonal shape in a top view.

The light-shielding member 13 preferably has light reflectivity in order to improve the light extraction efficiency of the light source 10. For example, the light-shielding member 13 is made of a resin material containing a light reflective material. Examples of the light reflective material include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. One of these is preferably used alone, or a combination of two or more of these are preferably used. Examples of the resin material include a resin material whose main component is a thermosetting resin such as an epoxy resin, an epoxy-modified resin, a silicone resin, a silicone-modified resin, and a phenol resin.

### [Lens 20]

The configuration of the lens 20 will be described below. The lens 20 is disposed above the light source 10. The lens 20 is optically transmissive with respect to light emitted by the light source 10 and external light reaching the light-emitting device 1. Examples of a material constituting the lens 20 include resin materials such as a polycarbonate resin, an acrylic resin, a silicone resin, and an epoxy resin, and glass materials. The expression that the lens 20 is “optically transmissive” refers to being configured to transmit 60% or more of light incident on the lens 20.

The lens 20 has the upper surface, the lower surface, and one or more lateral surfaces each connecting corresponding outer edges of the upper surface and the lower surface. The lens 20 has a substantially circular outer shape in a top view. However, the lens 20 may have an outer shape such as a substantially rectangular shape, a substantially elliptical shape, or a substantially polygonal shape in a top view.

An example of the lens 20 includes a Fresnel lens. As illustrated in FIG. 2, the lens 20 includes a plurality of protruding portions 21 on the lower surface of the lens 20. Each of the plurality of protruding portions 21 is arranged concentrically around the optical axis OA of the lens 20. In a top view, each of the plurality of protruding portions 21 has an annular outer shape arranged concentrically around the optical axis OA.

The plurality of protruding portions 21 includes one or more first protruding portions 211 located at positions overlapping the light source 10 in a top view, and one or more second protruding portions 212 located at positions overlapping the light-receiving element 30 in a top view. The second protruding portion 212 is located on an outer side of the lens 20 (that is, on the side farther from the optical axis OA of the lens 20) than the first protruding portion 211. Each of the first protruding portion 211 and the second protruding portion 212 corresponds to a respective one of a plurality of unit lenses constituting a Fresnel lens structure.

Each of the one or more first protruding portions 211 includes a tip portion 211B located on the lowermost side (−Z direction side), a first surface 211F located on an inner side of the lens 20 in a top view, and a second surface 211S located on an outer side of the lens 20 in a top view. The second surface 211S is connected to the first surface 211F via the tip portion 211B. The second surface 211S of the first protruding portion 211 corresponds to a lens surface of a Fresnel lens. The first surface 211F of the first protruding portion 211 corresponds to a rise surface connecting the lens surfaces of the Fresnel lens.

Each of the one or more second protruding portions 212 includes a tip portion 212B located on the lowermost side (−Z direction side), a first surface 212F located on an inner side of the lens 20 in a top view, and a second surface 212S located on an outer side of the lens 20 in a top view. The second surface 212S is connected to the first surface 212F via the tip portion 212B. The second surface 212S of the second protruding portion 212 corresponds to a lens surface of a Fresnel lens. The first surface 212F of the second protruding portion 212 corresponds to a rise surface connecting the lens surfaces of the Fresnel lens.

When the light source 10 is disposed at the center of the substrate 40 to intersect the optical axis OA of the lens 20, the light-receiving element 30 is disposed on an outer side of the substrate 40 with respect to the light source 10, and does not intersect with the optical axis OA of the lens 20. That is, the optical design related to the shape and the like of the lens 20 is adapted to the light source 10, but is not adapted to the light-receiving element 30 in many cases.

With reference to FIG. 3, a description will be given of the transition in the amount of light received by the light-receiving element disposed at a position intersecting with the optical axis OA depending on an incident angle of external light and the transition in the amount of light received by a light-receiving element (hereinafter, referred to as a conventional light-receiving element) disposed at a position not intersecting with the optical axis OA depending on an incident angle of external light. The conventional light-receiving element described below is assumed to be located closer to the −X direction with respect to the optical axis OA, similarly to the light-receiving element 30 of the present embodiment.

In a graph on the left side of FIG. 3, a horizontal axis indicates an incident angle of external light with respect to the lens 20 (hereinafter, referred to as “incident angle of external light”). The incident angle of the external light is based on the optical axis OA. The incident angle of the external light incident on the lens 20 in a direction parallel to the optical axis OA is “0°”. In FIG. 3, a vertical axis indicates the relative amount of light received by the light-receiving element 30. The vertical axis in FIG. 3 indicates the relative amount of received light when the amount of received light at an incident angle of each of a line S11 and a line S12 of 0° is set to 100%. In FIG. 3, the line S11 indicates the transition in the relative amount of light received by the light-receiving element disposed at the position intersecting with the optical axis OA. The line S12 indicates the transition in the relative amount of light received by the conventional light-receiving element disposed at the position not intersecting with the optical axis OA. In the following description, the relative amount of received light may be simply referred to as the “amount of received light”. In addition, an incident angle of external light (hereinafter, referred to as “external light incident from a +X side”) incident on the lens 20 in a direction from the +X side with respect to the optical axis OA, such as external light L14 and L15 illustrated in FIG. 2, is defined as a “positive incident angle”. For example, an incident angle “+θ” illustrated in an inset diagram on the right side of FIG. 3 is an example of the “positive incident angle”. On the other hand, an incident angle of external light (hereinafter, referred to as “external light incident from a −X side”) incident on the lens 20 in a direction from the −X side with respect to the optical axis OA, such as external light L11 and L12 illustrated in FIG. 2, is defined as a “negative incident angle”. An incident angle “−θ” illustrated in the inset diagram on the right side of FIG. 3 is an example of the “negative incident angle”.

As indicated by the line S11 in FIG. 3, the amount of light received by the light-receiving element disposed at the position intersecting with the optical axis OA is the largest when the incident angle of the external light is 0°. On the other hand, as the incident angle of the external light increases, the amount of light received by the light-receiving element disposed at the position intersecting with the optical axis OA decreases. That is, the line S11 in FIG. 3 has a substantially line-symmetric shape.

In contrast, in the transition in the amount of light received by the conventional light-receiving element indicated by the line S12 in FIG. 3, the amount of received external light incident at the positive incident angle is larger than the amount of received external light incident at the negative incident angle. Specifically, external light incident from the −X side such as the external light L11 and the external light L12 in FIG. 2 hardly reaches the conventional light-receiving element because the conventional light-receiving element is shifted in the −X direction. Therefore, the amount of received external light incident from the −X side decreases. On the other hand, external light incident from the +X side such as the external light L14 and the external light L15 easily reaches the conventional light-receiving element because the conventional light-receiving element is shifted in the −X direction. Therefore, the amount of received external light incident from the +X side increases. That is, the line S12 in FIG. 3 has an asymmetrical shape.

As described above, in the conventional light-receiving element, variation in the amount of received light (hereinafter, referred to as “variation in the amount of received light”) may occur depending on an incident angle of external light with respect to the lens 20. Therefore, the conventional light-receiving element may not be able to appropriately detect the amount of external light corresponding to the incident angle.

In this regard, in order to reduce variation in the amount of received light, the lens 20 includes a light adjustment part configured to adjust the amount of external light received by the light-receiving element 30. In a top view, the light adjustment part is provided in at least a region of the lens 20 overlapping the light-receiving element 30.

A light adjustment part 212R of the present embodiment is a rough surface provided in at least a region of the second surface 212S of the second protruding portion 212 in the lens 20 (see FIG. 2, FIG. 4, and FIG. 5). The light adjustment part 212R is preferably provided in the entire region of the second surface 212S of the second protruding portion 212. That is, the light adjustment part 212R is continuously disposed in an annular region around the optical axis OA. Thus, the appearance of the light-emitting device 1 can be improved due to the geometric symmetry when the light-emitting device 1 is viewed from the outside. For example, when the first surface 212F and the second surface 212S (see FIG. 2) of the second protruding portion 212 are rough surfaces, the light adjustment part 212R corresponds to the first surface 212F and the second surface 212S of the second protruding portion 212. When only the second surface 212S of the second protruding portion 212 is a rough surface, the light adjustment part 212R corresponds to the second surface 212S of the second protruding portion 212.

The rough surface as the light adjustment part 212R is preferably an embossed surface. By forming an embossed surface as the light adjustment part 212R, fine surface unevenness for roughening the second surface 212S of the second protruding portion 212 can be easily formed. The rough surface as the light adjustment part 212R may be formed in the first surface 212F of the second protruding portion 212. The light adjustment part 212R is not limited to the embossed surface.

The light adjustment part 212R may have a configuration other than the rough surface. Examples of the light adjustment part 212R having other configuration include a light diffusion material or the like contained in the second protruding portion 212.

Examples of the light diffusion material include titanium oxide, barium titanate, aluminum oxide, and silicon oxide. However, the light diffusion material may be a material other than these materials.

The second protruding portion 212 with the light adjustment part 212R is disposed outside the light source 10 in a top view. That is, the light adjustment part 212R is disposed at a position not intersecting with an optical path of light incident on the lens 20 from the light source 10. Therefore, the light adjustment part 212R has less influence on lens design related to the lens 20.

With the light adjustment part 212R provided on the second protruding portion 212 of the lens 20, external light exiting the lower surface of the lens 20 can be scattered. Specifically, as illustrated in FIG. 4, when external light incident from the −X side, such as the external light L11 and L12, exiting the lower surface of the lens 20, the external light impinges on the unevenness of the light adjustment part 212R and is scattered. Thus, the external light incident from the −X side is diffused in random directions, so that the amount of external light reaching the light-receiving element 30 can be increased. As illustrated in FIG. 5, when external light incident from the +X side, such as the external light L14 and L15, exiting the lower surface of the lens 20, the external light impinges on the unevenness of the light adjustment part 212R and is scattered. Thus, the external light incident from the +X side is diffused in random directions, so that the amount of external light reaching the light-receiving element 30 can be reduced. As a result, variation in the amount of received light can be reduced. In addition, a light reception signal output from the light-receiving element 30 appropriately reflects the amount of external light. Thus, the accuracy in adjusting the amount of light emitted by the light source 10 can be improved.

With the light adjustment part 212R provided on the second protruding portion 212 of the lens 20, light incident on the lens 20 from the light source 10 can be diffused by the light adjustment part 212R and emitted from the upper surface of the lens 20. Thus, the emitted light with reduced directivity can be emitted from the light-emitting device 1. Further, providing the light adjustment part 212R allows for improving the uniformity of illuminance of light emitted from the light-emitting device 1.

### [Light-Receiving Element 30]

The configuration of the light-receiving element 30 will be described below. As illustrated in FIG. 2, the light-receiving element 30 is disposed at a position not intersecting with the optical axis OA of the lens 20. Specifically, the light-receiving element 30 is closer to the −X direction relative to the optical axis OA. However, the light-receiving element 30 may be closer to the +X direction, the +Y direction, or the −Y direction relative to the optical axis OA.

The light-receiving element 30 includes an element housing 31 disposed on the substrate 40, a light-receiving portion 32 disposed on the element housing 31, and a light-transmissive covering member 33 covering the element housing 31 and the light-receiving portion 32. The light-receiving element 30 is connected to the wiring of the substrate 40 through, for example, a metal wiring such as a wire. Thus, power from the external power source is supplied to the light-receiving element 30. Further, an electric signal indicating the amount of light received by the light-receiving element 30 is transmitted to, for example, a signal processing unit included in the smartphone.

In the light-receiving element 30, the light-receiving portion 32 is a component that receives external light. The light-receiving portion 32 is disposed on the upper surface of the light-receiving element 30. The light-receiving portion 32 has a substantially rectangular outer shape in a top view. However, the light-receiving portion 32 may have another outer shape such as a substantially circular shape, a substantially elliptical shape, or a substantially polygonal shape in top a view.

Examples of the light-receiving element 30 include a photoelectric conversion element such as a photodiode or a phototransistor. As illustrated in FIG. 2, the light-receiving portion 32 is located closer to the +X direction side on the upper surface of the light-receiving element 30. The position of the light-receiving portion 32 is not limited thereto.

### Example of Effect of Reducing Variation in Amount of Received Light Due to Difference in Spread Angle σ of External Light

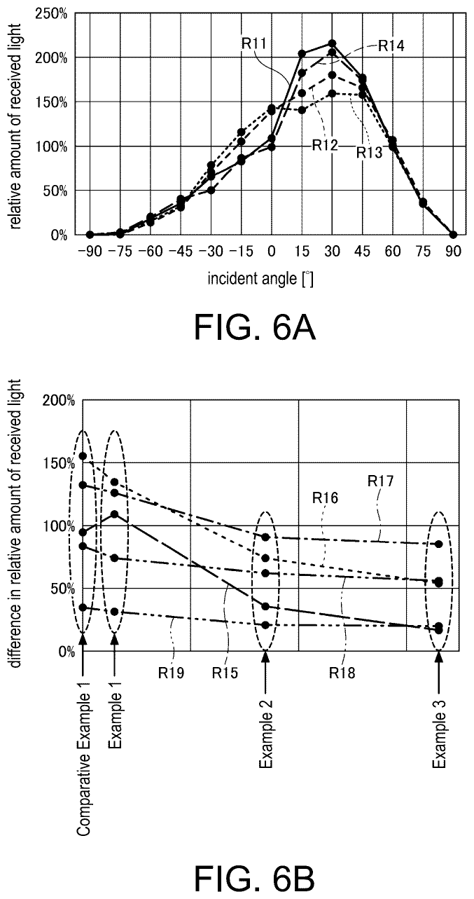

The following describes an example of the effect of reducing variation in the amount of received light due to a difference in a spread angle σ (hereinafter, referred to as “spread angle σ”) of external light diffused by the light adjustment part 212R of the lens 20 with reference to FIG. 6A and FIG. 6B.

A simulation was performed to show an example of the effect of reducing variation in the amount of received light. In the present simulation, Examples 1 to 3 having different spread angles σ and Comparative Example 1 including no light adjustment part 212R were used. Note that in each of Examples 1 to 3, the first surface 212F and the second surface 212S of the second protruding portion 212 are roughened. That is, the light adjustment part 212R in Examples 1 to 3 corresponds to the first surface 212F and the second surface 212S of the second protruding portion 212.

The spread angles σ in Examples 1 to 3 are as follows.
(1) Example 1: σ=3.0°
(2) Example 2: σ=17.0°
(3) Example 3: σ=33.0°

Note that external light exiting a lower surface of a lens in Comparative Example 1 is not diffused. That is, the spread angle σ in Comparative Example 1 is “0°”.

The spread angle σ corresponds to the surface roughness of the light adjustment part 212R. As the spread angle σ increases, the surface roughness of the light adjustment part 212R increases. The surface roughness in Example 1 is the smallest and the surface roughness in Example 3 is the largest. The surface roughness in Example 2 has a value between the surface roughness in Example 1 and the surface roughness in Example 3.

Specifically, surface roughnesses Ra in Examples 1 to 3 corresponding to the spread angles σ are as follows.
(1) Example 1: Ra=0.6 μm
(2) Example 2: Ra=2.2 μm
(3) Example 3: Ra=6.3 μm

A surface roughness Ra in Comparative Example 1 corresponds to “0.0 μm”.

FIG. 6A is a graph showing the transition in the amount of light received by the light-receiving element 30 depending on an incident angle of external light in the present simulation. In FIG. 6A, a horizontal axis indicates the incident angle of the external light. In FIG. 6A, a vertical axis indicates the relative amount of received light based on the amount of received light at an incident angle of 0° in Comparative Example 1. In FIG. 6A, a line R11 indicates the transition in the amount of received light depending on the incident angle of the external light in Example 1. A line R12 indicates the transition in the amount of received light depending on the incident angle of the external light in Example 2. A line R13 indicates the transition in the amount of received light depending on the incident angle of the external light in Example 3. A line R14 indicates the transition in the amount of received light depending on the incident angle of the external light in Comparative Example 1.

As illustrated in FIG. 6A, in Comparative Example 1 including no light adjustment part 212R, a difference between the amount of received external light incident from the +X side and the amount of received external light incident from the −X side is large. That is, variation in the amount of received light is large. On the other hand, in Examples 1 to 3, as the spread angle σ increases, the difference between the amount of received external light incident from the +X side and the amount of received external light incident from the −X side decreases. As an example, in Examples 1 to 3, the relative amount of received light at −30° is relatively larger than the relative amount of received light at −30° in the Comparative Example 1, and the relative amount of received light at +30° is relatively smaller than the relative amount of received light at +30° in the Comparative Example 1. That is, it was shown that variation in the amount of received light is reduced as the surface roughness of the light adjustment part 212R increases.

FIG. 6B is a graph in which a difference in the relative amount of received light between two types of external light at the same incident angle is plotted for each of Examples 1 to 3 and Comparative Example 1. The “two types of external light at the same incident angle” refers to a set of two types of external light that are at positive and negative incident angles of the same θ, which represents a degree of an angle, such as external light at the incident angle +θ and external light at the incident angle −θ illustrated in FIG. 3. Examples of the two types of external light at the same incident angle include a set of external light at an incident angle of +15° and external light at an incident angle of −15° (hereinafter, referred to as “external light of Δ15°”), a set of external light at an incident angle of +30° and external light at an incident angle of −30° (hereinafter, referred to as “external light of Δ30°”), a set of external light at an incident angle of +45° and external light at an incident angle of −45° (hereinafter, referred to as “external light of Δ45°”), a set of external light at an incident angle of +60° and external light at an incident angle of −60° (hereinafter, referred to as “external light of Δ60°”), and a set of external light at an incident angle of +75° and external light at an incident angle of −75° (hereinafter, referred to as “external light of Δ 75°”).

In FIG. 6B, points on a line R15 indicate differences in the relative amounts of received external light of Δ15° in Examples 1 to 3 and Comparative Example 1. Points on a line R16 indicate differences in the relative amounts of received external light of Δ30° in Examples 1 to 3 and Comparative Example 1. Points on a line R17 indicate differences in the relative amounts of received external light of Δ45° in Examples 1 to 3 and Comparative Example 1. Points on a line R18 indicates differences in the relative amounts of received external light of Δ60°. Points on a line R19 indicates differences in the relative amounts of received external light of Δ75°.

As illustrated in FIG. 6B, in Example 1, it was confirmed that the differences in the relative amounts of received light are small for the external light of Δ30°, the external light of Δ45°, the external light of Δ60°, and the external light of Δ75°. In Examples 2 and 3, it was confirmed that the differences in the relative amount of received light are small for the external light of Δ15°, the external light of Δ30°, the external light of Δ45°, the external light of Δ60°, and the external light of Δ75°.

As illustrated in FIG. 6B, for the external light of Δ15°, the differences in the relative amounts of received light were successively smaller in the order of Example 1, Example 2, and Example 3 in which the spread angle σ increases in the order. Similarly, for each of the external light of Δ30°, the external light of Δ45°, the external light of Δ60°, and the external light of Δ75°, the differences in the relative amounts of received light were successively smaller in the order of Example 1, Example 2, and Example 3 in which the spread angle σ increases in the order. That is, as the surface roughness of the light adjustment part 212R increases, the difference between the amount of received external light incident from the +X side and the amount of received external light incident from the −X side was small.

### Another Example of Effect of Reducing Variation in Amount of Received Light Due to Difference in Spread Angle σ of External Light

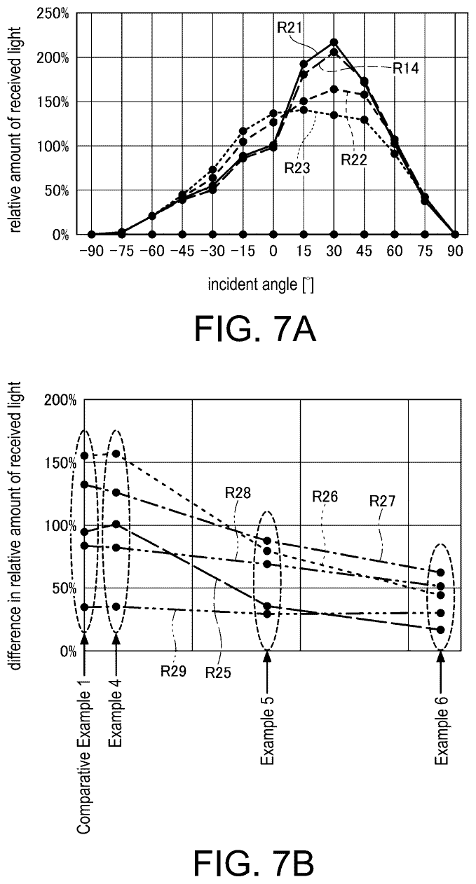

The following describes another example of the effect of reducing variation in the amount of received light due to a difference in the spread angle σ of external light diffused by the light adjustment part 212R of the lens 20 with reference to FIG. 7A and FIG. 7B. A simulation similar to the simulation illustrated in FIG. 6A and FIG. 6B was performed for the following Examples 4 to 6. FIG. 7A and FIG. 7B illustrate the effect of reducing variation in the amount of received light as an example, and the effect of reducing variation in the amount of received light according to the present embodiment is not limited to the result of the present simulation.

The present simulation is different from the simulation illustrated in FIG. 6A and FIG. 6B in that only the second surface 212S of the second protruding portion 212 is roughened in Examples 4 to 6. The other points are the same as those of the simulation illustrated in FIG. 6A and FIG. 6B. The light adjustment part 212R in Examples 4 to 6 corresponds to the second surface 212S of the second protruding portion 212.

The spread angles σ in Examples 4 to 6 are as follows.
(4) Example 4: σ=3.0° (corresponding to Ra of 0.6 μm)
(5) Example 5: σ=17.0° (corresponding to Ra of 2.2 μm)
(6) Example 6: σ=33.0° (corresponding to Ra of 6.3 μm)

FIG. 7A is a graph showing the transition in the amount of received light depending on an incident angle of external light in the present simulation. In FIG. 7A, a horizontal axis indicates the incident angle of the external light. In FIG. 7A, a vertical axis indicates the relative amount of received light based on the amount of received light at an incident angle of 0° in Comparative Example 1. In FIG. 7A, a line R21 indicates the transition in the amount of received light depending on the incident angle of the external light in Example 4. A line R22 indicates the transition in the amount of received light depending on the incident angle of the external light in the Example 5. A line R23 indicates the transition in the amount of received light depending on the incident angle of the external light in the Example 6. A line R14 indicates the transition in the amount of received light depending on the incident angle of the external light in Comparative Example 1.

As illustrated in FIG. 7B, in Example 4, it was confirmed that the differences in the relative amounts of received light become small for the external light of Δ45°, the external light of Δ60°, and the external light of Δ75°. In Examples 5 and 6, it was confirmed that the differences in the relative amounts of received light become small for the external light of Δ15°, the external light of Δ30°, the external light of Δ45°, the external light of Δ60°, and the external light of Δ75°.

As illustrated in FIG. 7A, in Examples 4 to 6, as the spread angle σ increases, the difference between the amount of received external light incident from the +X side and the amount of received external light incident from the −X side was small. That is, as the surface roughness of the light adjustment part 212R increases, variation in the amount of received light was reduced. As an example, in Examples 4 to 6, the relative amount of received light at −30° is relatively larger than the relative amount of received light at −30° in the Comparative Example 1, and the relative amount of received light at +30° is relatively smaller than the relative amount of received light at +30° in the Comparative Example 1. It was shown that roughening the second surface 212S of the second protruding portion 212 allows for reducing the directivity of external light incident from the +X side, which easily reaches the light-receiving element 30, and reducing variation in the amount of received light can be reduced.

FIG. 7B is a graph in which a difference in the relative amount of received light between two types of external light at the same incident angle is plotted for each of Examples 4 to 6 and Comparative Example 1. In FIG. 7B, points on a line R25 indicate differences in the relative amounts of received external light of Δ15° in Examples 4 to 6 and Comparative Example 1. Points on a line R26 indicate differences in the relative amounts of received external light of Δ30° in Examples 4 to 6 and Comparative Example 1. Points on a line R27 indicate differences in the relative amounts of received external light of Δ45° in Examples 4 to 6 and Comparative Example 1. Points on a line R28 indicate differences in the relative amounts of received external light of Δ60° in Examples 4 to 6 and Comparative Example 1. Points on a line R29 indicate differences in the relative amounts of received external light of Δ75° in Examples 4 to 6 and Comparative Example 1.

As illustrated in FIG. 7B, the differences in the relative amounts of received external light of Δ15° were successively smaller in the order of Example 4, Example 5, and Example 6 in which the spread angle σ increases in the order. Similarly, the differences in the relative amounts of received external light of Δ30°, the differences in the relative amounts of received external light of Δ45°, the differences in the relative amounts of received external light of Δ60°, and the differences in the relative amounts of received external light of Δ75° were successively smaller in the order of Example 4, Example 5, and Example 6 in which the spread angle σ increases in the order. It was shown that roughening the second surface 212S of the second protruding portion 212 allows for reducing the directivity of external light incident from the +X side, which easily reaches the light-receiving element 30, and reducing variation in the amount of received light.

### Second Embodiment

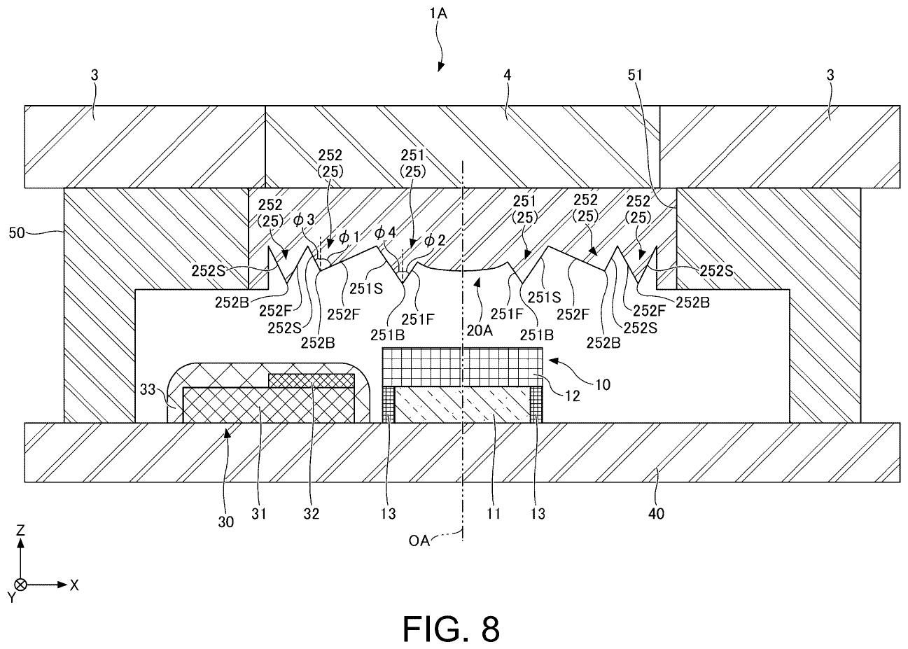

A light-emitting device 1A according to a second embodiment will be described with reference to FIG. 8. FIG. 8 is a schematic cross-sectional view of the light-emitting device 1A taken along an XZ plane. The light-emitting device 1A according to the second embodiment is different from the first embodiment in the structure of a light adjustment part provided in a lens 20A.

The light-emitting device 1A according to the present embodiment includes the light source 10, the lens 20A, and the light-receiving element 30. The light-emitting device 1A further includes the substrate 40 on which the light source 10 and the light-receiving element 30 are mounted, and the support portion 50 supporting the lens 20A. In the light-emitting device 1A illustrated in FIG. 8, the light-receiving portion 32 of the light-receiving element 30 is located closer to the +X direction side on the upper surface of the light-receiving element 30.

An example of the lens 20A includes a Fresnel lens. The lens 20A includes a plurality of protruding portions 25 on the lower surface thereof. The plurality of protruding portions 25 are arranged concentrically around an optical axis OA of the lens 20A. As illustrated in FIG. 8, each of the plurality of protruding portions 25 has an annular outer shape arranged concentrically around the optical axis OA in a top view.

In a top view, the plurality of protruding portions 25 include one or more first protruding portions 251 disposed at positions overlapping the light source 10 and one or more second protruding portions 252 disposed at positions overlapping the light-receiving element 30. The second protruding portion 252 is disposed on an outer side of the lens 20A than the first protruding portion 251. The first protruding portion 251 and the second protruding portion 252 correspond to a plurality of unit lenses in a Fresnel lens structure.

Each of the one or more first protruding portions 251 includes a tip portion 251B located on the lowermost side (−Z direction side), a first surface 251F located on an inner side of the lens 20A in a top view, and a second surface 251S located on an outer side of the lens 20A in a top view. The second surface 251S is connected to the first surface 251F via the tip portion 251B. The second surface 251S of the first protruding portion 251 corresponds to a lens surface of a Fresnel lens. The first surface 251F of the first protruding portion 251 corresponds to a rise surface connecting the lens surfaces of the Fresnel lens.

Each of the one or more second protruding portions 252 includes a tip portion 252B located on the lowermost side (−Z direction side), a first surface 252F located on an inner side of the lens 20A in a top view, and a second surface 252S located on an outer side of the lens 20A in a top view. The second surface 252S is connected to the first surface 252F via the tip portion 252B. The second surface 252S of the second protruding portion 252 corresponds to a lens surface of a Fresnel lens. The first surface 252F of the second protruding portion 252 corresponds to a rise surface connecting the lens surfaces of the Fresnel lens.

As illustrated in FIG. 8, the first surface 252F of at least one second protruding portion 252 has an inclined surface having a larger inclination angle with respect to the optical axis OA of the lens 20A than the first surface 251F of the first protruding portion 251. That is, an inclination angle φ1 of the first surface 252F of the second protruding portion 252 with respect to the optical axis OA of the lens 20A is greater than an inclination angle φ2 of the first surface 251F of the first protruding portion 251 with respect to the optical axis OA of the lens 20A. The inclined surface of the first surface 252F corresponds to the light adjustment part of the lens 20A. In a top view, the inclined surface of the first surface 252F is located in at least a region overlapping the light-receiving element 30. In the present embodiment, the inclined surface of the first surface 252F is located over the entire region of the first surface 252F. That is, the light adjustment part is continuously disposed in an annular region around the optical axis OA. Thus, the appearance of the light-emitting device 1A can be improved due to the geometric symmetry when the light-emitting device 1A is viewed from the outside.

As illustrated in FIG. 8, a width of at least one second protruding portion 252 is preferably larger than a width of the first protruding portion 251 in a radial direction of the lens 20A (direction from the optical axis OA to the outer side in an XY plane). In a height direction of the lens 20A (direction along the Z direction), the tip portion 252B of at least one second protruding portion 252 is preferably located above (on the +Z direction side of) the position of the tip portion 251B of the first protruding portion 251.

With the lens 20A in which the inclination angle φ1 of the first surface 252F of the second protruding portion 252 with respect to the optical axis OA is set to be larger than the inclination angle φ2 of the first surface 251F of the first protruding portion 251, the difference between the amount of external light on the +X side that reaches the light-receiving element 30 and the amount of external light on the −X side that reaches the light-receiving element 30 can be reduced.

The shape of the first surface 252F overlapping the light-receiving element 30 in a top view is determined so that external light incident on the first surface 252F is guided to the light-receiving element 30. With the light-receiving element 30 located closer to the −X side than the optical axis OA, the amount of external light entering the light-receiving element 30 from the −X side is reduced by being blocked by the housing 3 or the like. Therefore, in order to facilitate guiding the external light entering from the −X side to the light-receiving element 30, the first surface 252F of the second protruding portion 252 located on the +X side serves as a light adjustment part and has an inclined surface inclined at a larger inclination angle with respect to the optical axis OA of the lens 20A than that of the first surface 251F of the first protruding portion 251. Thus, the difference between the amount of external light on the +X side that reaches the light-receiving element 30 and the amount of external light on the −X side that reaches the light-receiving element 30 can be reduced, and variation in the amount of received light can be reduced. In addition, a light reception signal output from the light-receiving element 30 appropriately reflects the amount of external light. Thus, the adjustment accuracy of the amount of light emitted by the light source 10 can be improved.

With the width of the second protruding portion 252 larger than the width of the first protruding portion 251, the second protruding portion 252 can be closer to a flat state than the first protruding portion 251. This can facilitate designing of the second protruding portion 252. With the tip portion 252B of the second protruding portion 252 positioned above the position of the tip portion 251B of the first protruding portion 251, the second protruding portion 252 can be closer to a flat state than the first protruding portion 251. This can facilitate designing the second protruding portion 252. As illustrated in FIG. 8, the tip portion 252B of the second protruding portion 252 is closer to the outer side than the center of the width of the second protruding portion 252. The second surface 252S of the second protruding portion 252 is an inclined surface at a smaller inclination angle with respect to the optical axis OA of the lens 20A than that of the second surface 251S of the first protruding portion 251. That is, an inclination angle φ3 of the second surface 252S of the second protruding portion 252 with respect to the optical axis OA of the lens 20A is smaller than an inclination angle φ4 of the second surface 251S of the first protruding portion 251 with respect to the optical axis OA of the lens 20A. The shape of the second surface 252S may be determined such that the shape allows for guiding external light incident on the second surface 252S to the outside of the light-receiving element 30.

### Example of Effect of Reducing Variation in Amount of Received Light Depending on Presence or Absence of Light Adjustment Part

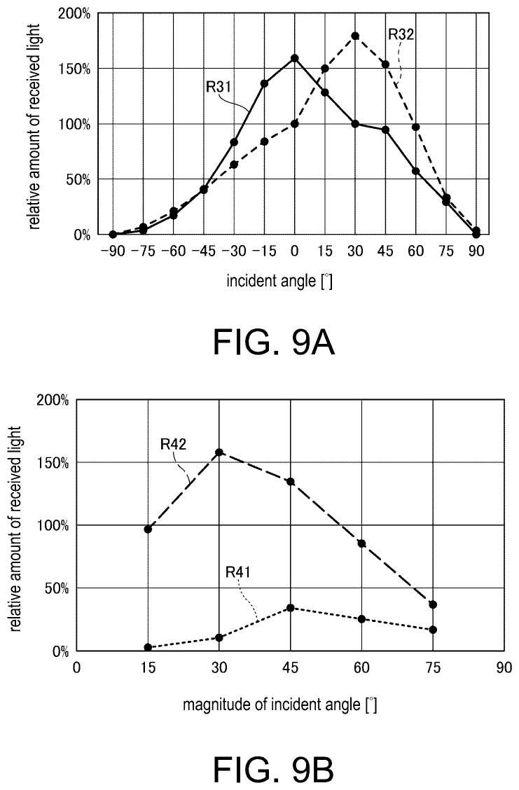

The following describes an example of the effect of reducing variation in the amount of received light depending on the presence or absence of the light adjustment part with reference to FIG. 9A and FIG. 9B. A simulation was performed to show an example of the effect of reducing variation in the amount of received light. Example 7 used in the present simulation includes the light adjustment part described with reference to FIG. 8. That is, in Example 7, the inclination angle φ1 of the first surface 252F of the second protruding portion 252 with respect to the optical axis OA is larger than the inclination angle φ2 of the first surface 251F of the first protruding portion 251 with respect to the optical axis OA. In Example 7, the width of the second protruding portion 252 is larger than the width of the first protruding portion 251. In Example 7, the tip portion 252B of the second protruding portion 252 is located above the position of the tip portion 251B of the first protruding portion 251. In contrast, in a Fresnel lens in Comparative Example 2, the plurality of protruding portions at the lower surface thereof does not have a shape characteristic as that of the light adjustment part of Example 7, such as that the height of the tip portion of the first protruding portion and the tip portion of the second protruding portion are different from each other. FIG. 9A and FIG. 9B illustrate the effect of reducing variation in the amount of received light as an example, and the effect of reducing variation in the amount of received light according to the present embodiment is not limited to the result of this simulation.

FIG. 9A is a graph showing the transition in the amount of light received by the light-receiving element 30 depending on an incident angle of external light in this simulation. In FIG. 9A, a horizontal axis indicates the incident angle of the external light. In FIG. 9A, a vertical axis indicates the relative amount of received light based on the amount of received light at an incident angle of 0° in Comparative Example 2. In FIG. 9A, a line R31 indicates the transition in the amount of received light depending on the incident angle of the external light in Example 7. A line R32 indicates the transition in the amount of received light depending on the incident angle of the external light in Comparative Example 2.

As illustrated in FIG. 9A, the line R31 corresponding to Example 7 has a nearly line-symmetrical shape, in which the amount of received light decreases as the incident angle of the external light increases, with the amount of received external light at the incident angle of 0° serving as a boundary. The light adjustment part of the present embodiment can reduce the difference between the amount of external light on the +X side that reaches the light-receiving element 30 and the amount of external light on the −X side that reaches the light-receiving element 30. Thus, it was shown that variation in the amount of received light can be reduced by providing the light adjustment part of the present embodiment.

FIG. 9B is a graph showing a difference in the relative amount of received light between two types of external light at the same incident angle in Example 7 and Comparative Example 2. A difference in the relative amount of received light at “15°” on the horizontal axis in FIG. 9B corresponds to a difference in the relative amounts of received external light of Δ15°. A difference in the relative amount of received light at “30°” on the horizontal axis in FIG. 9B corresponds to a difference in the relative amounts of received external light of Δ30°. A difference in the relative amount of received light at “45°” on the horizontal axis in FIG. 9B corresponds to a difference in the relative amounts of received external light of Δ45°. A difference in the relative amount of received light at “60°” on the horizontal axis in FIG. 9B corresponds to a difference in the relative amounts of received external light of Δ60°. A difference in the relative amount of received light at “75°” on the horizontal axis in FIG. 9B corresponds to a difference in the relative amounts of received external light received of Δ75°.

In FIG. 9B, a line R41 indicates the difference in the relative amounts of received light between the two types of external light at the same incident angle in Example 7. In FIG. 9B, a line R42 indicates the difference in the relative amounts of received light between the two types of external light at the same incident angle in Comparative Example 2. As illustrated in FIG. 9B, the difference in the relative amounts of the received external light of Δ15°, the difference in the relative amounts of the received external light of Δ30°, the difference in the relative amounts of the received external light of Δ45°, the difference in the relative amounts of the received external light of Δ60°, and the difference in the relative amounts of the received external light of Δ75° in Example 7 were all reduced as compared with Comparative Example 2. That is, from this point of view as well, the effect of reducing variation in the amount of received light by the light adjustment part of the present embodiment was shown.

Although the preferred embodiments and the like have been described in detail above, the disclosure is not limited to the above-described embodiments and the like, various modifications and substitutions can be made to the above-described embodiments and the like without departing from the scope described in the claims. For example, in the second embodiment, the first surface 252F and the second surface 252S of the second protruding portion 252 may be roughened as in the light adjustment part 212R of the first embodiment.

What is claimed is:

1. A light-emitting device comprising:
a light source;
a lens disposed above the light source; and
a light-receiving element disposed at a position not intersecting with an optical axis of the lens, the light-receiving element being configured to receive external light via the lens,
wherein the lens comprises a light adjustment part in a region overlapping the light-receiving element in a top view, and the light adjustment part is configured to adjust an amount of external light received by the light-receiving element.

2. The light-emitting device according to claim 1, wherein
the lens comprises a plurality of protruding portions disposed concentrically around the optical axis on a lower surface of the lens facing the light source,
the plurality of protruding portions comprises:
one or more first protruding portions overlapping the light source in the top view, and
one or more second protruding portions disposed outward of the first protruding portion and overlapping the light-receiving element,
each of the first protruding portion and the second protruding portion comprises:
a tip portion located on a lowermost side of the first protruding portion or the second protruding portion;
a first surface located on an inner side of the lens in the top view; and
a second surface located on an outer side of the lens and connected to the first surface via the tip portion in the top view, and
the second surface of the second protruding portion is served as the light adjustment part.

3. The light-emitting device according to claim 1, wherein the light adjustment part is a rough surface.

4. The light-emitting device according to claim 3, wherein the rough surface is an embossed surface.

5. The light-emitting device according to claim 2, wherein the light adjustment part is continuously disposed in an annular region around the optical axis of the lens.

6. The light-emitting device according to claim 2, wherein the light adjustment part is disposed outside the light source in the top view.

7. The light-emitting device according to claim 1, wherein
the lens comprises a plurality of protruding portions arranged concentrically around the optical axis on a lower surface of the lens facing the light source,
the plurality of protruding portions comprises:
one or more first protruding portions overlapping the light source in the top view, and
one or more second protruding portions disposed on an outer side of the first protruding portion and overlapping the light-receiving element in the top view,
each of the first protruding portion and the second protruding portion comprises:
a tip portion located on a lowermost side of the first protruding portion or the second protruding portion;
a first surface located on an inner side of the lens in the top view; and
a second surface located on an outer side of the lens and connected to the first surface via the tip portion in the top view, and
the first surface of the second protruding portion is served as the light adjustment part.

8. The light-emitting device according to claim 7, wherein the first surface of the second protruding portion has an inclined surface as the light adjustment part, and an inclination angle of the inclined surface with respect to the optical axis of the lens is larger than an inclination angle of the first surface of the first protruding portion with respect to the optical axis of the lens.

9. The light-emitting device according to claim 7, wherein, in a radial direction of the lens, a width of the second protruding portion is larger than a width of the first protruding portion.

10. The light-emitting device according to claim 9, wherein, in a height direction of the lens, the tip portion of the second protruding portion is located at a position higher than a position of the tip portion of the first protruding portion.

11. The light-emitting device according to claim 7, wherein the light adjustment part is continuously disposed in an annular region around the optical axis of the lens.

12. The light-emitting device according to claim 7, wherein the light adjustment part is disposed outside the light source in the top view.

13. The light-emitting device according to claim 1, wherein
the light source comprises:
a light-emitting element, and
a wavelength conversion member disposed on the light-emitting element.

14. The light-emitting device according to claim 1, wherein
both of the first surface and the second surface of the second protruding portion are served as the light adjustment part.

15. The light-emitting device according to claim 1, wherein
only the second surface of the second protruding portion is served as the light adjustment part.
